(19) United States
(12) Patent Application Publication
(10) Pub. No.: US 2019/0348317 A1
(43) Pub. Date: Nov. 14, 2019

(54) EDGE RING OR PROCESS KIT FOR SEMICONDUCTOR PROCESS MODULE

(71) Applicant: Applied Materials, Inc., Santa Clara, CA (US)

(72) Inventors: Allen L. D'AMBRA, Burlingame, CA (US); Sheshraj L. TULSHIBAGWALE, Santa Clara, CA (US)

(21) Appl. No.: 16/518,940

(22) Filed: Jul. 22, 2019

Related U.S. Application Data
(62) Division of application No. 15/679,040, filed on Aug. 16, 2017.
(60) Provisional application No. 62/378,492, filed on Aug. 23, 2016.

(51) Int. Cl. H01L 21/687; H01J 37/32; H01L 21/683

(52) U.S. Cl. CPC H01L 21/68735; H01J 37/32917; H01J 2237/334; H01J 37/32642; H01L 21/6833; H01J 37/32798

(57) ABSTRACT

The present invention generally relates method and apparatus for detecting erosion to a ring assembly used in an etching or other plasma processing chamber. In one embodiment, a method begins by obtaining a metric indicative of wear on a ring assembly disposed on a substrate support in a plasma processing chamber prior to processing with plasma in the plasma processing chamber. The metric for the ring assembly is monitored with a sensor. A determination is made if the metric exceeds a threshold and generating a signal in response to the metric exceeding the threshold.

### CROSS-REFERENCE TO RELATED APPLICATIONS

This application claims benefit of U.S. Provisional Application Ser. No. 62/378,492, filed Aug. 23, 2016 (Attorney Docket No. APPM/23941USL), and is a divisional of U.S. patent application Ser. No. 15/679,040, filed Aug. 16, 2017 (Attorney Docket No. APPM/23941US) both of which are incorporated by reference in their entirety.

### BACKGROUND OF THE INVENTION

### Field of the Invention

Embodiments of the present invention generally relate to a ring and ring assembly for an etching or other plasma processing chamber.

### Description of the Related Art

In semiconductor processing chambers, substrates undergo various processes such as deposition, etching and annealing. During some of the processes, the substrate is placed onto a substrate support such as an electrostatic chuck (ESC), for processing. In an etch process a ring may be placed around the substrate to prevent erosion of the areas of the substrate support that are not covered by the substrate. The ring focuses the plasma and positions the substrate in place.

Rings are usually made of quartz or silicon based material and are highly consumed in the etch process as they are exposed to etching gases and/or fluids. The rings are etched by the plasma during wafer processing and eventually begin to erode. The erosion of the rings leads to process drift after sufficient material removed from the ring changes the profile of the processing plasma along the edge of substrate. The process drift ultimately leads to defects on the substrates. The rings that are significantly eroded are usually replaced to ensure process conformity and prevent the manufacturing defects from affecting processing yields. However, replacing the rings requires the manufacturing process equipment to be shutdown which is expensive. There is a tradeoff of between shutting down the manufacturing process to replace the rings prior to generating defects and significantly reducing the service life of the ring and lowering manufacturing yields.

Thus, there is a need in the art monitoring the manufacturing process and extending yields.

### SUMMARY OF THE INVENTION

The present invention generally relates method and apparatus for detecting erosion to a ring assembly used in an etching or other plasma processing chamber. In one embodiment, a method begins by obtaining a metric indicative of wear on a ring assembly disposed on a substrate support in a plasma processing chamber prior to processing with plasma in the plasma processing chamber. The metric for the ring assembly is monitored with a sensor. A determination is made if the metric exceeds a threshold and generating a signal in response to the metric exceeding the threshold.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic, cross sectional view of an exemplary substrate support with a ring assembly disposed in a process chamber.

FIGS. 2A-2C are plan views for a portion of the processing chamber of FIG. 1 in the area of the ring assembly according to a first embodiment of the invention.

FIGS. 3A-3C are plan views for a portion of the processing chamber of FIG. 1 in the area of the ring assembly according to a second embodiment of the invention.

FIGS. 4A-4B are plan views for a portion of the processing chamber of FIG. 1 in the area of the ring assembly according to a third embodiment of the invention.

FIGS. 5A-5C are plan views for a portion of the processing chamber of FIG. 1 in the area of the ring assembly according to a fourth embodiment of the invention.

FIGS. 6A-6C are plan views for a portion of the processing chamber of FIG. 1 in the area of the ring assembly according to a fifth embodiment of the invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In a processing chamber used for semiconductor manufacturing, edge rings are used as part of the process kit surrounding the wafer/substrate. The substrate sits on top of a pedestal or an electrostatic chuck which usually has a step feature for installation of the edge ring. The edge ring is used to control the process performance on the substrate in the processing chamber. Monitoring degradation or erosion of the edge ring permits the edge ring to be replaced prior to the processing performance drifting out of specification. Contemporary methods of monitoring edge ring erosion are empirically determined. Embodiments disclosed below provide active or in-situ monitoring of the edge ring erosion over time (RF hours) to limit or prevent the process drift from exceeding allowable thresholds. This allows semiconductor manufacturers to implement scheduled preventative maintenance accurately and to optimize the life of the process kits in the chambers without sacrificing performance.

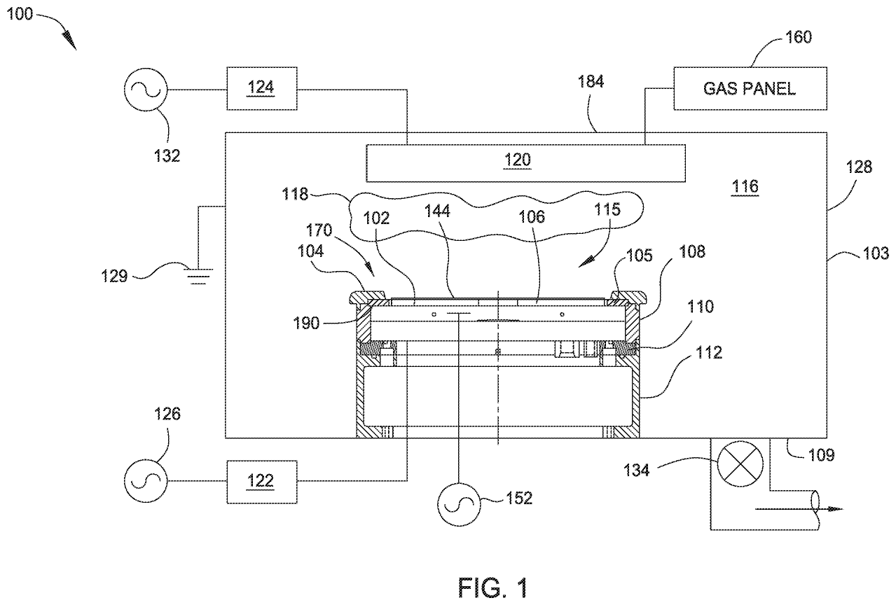

FIG. 1 is a schematic, cross sectional view of an exemplary substrate support 115 with a cover ring 104 disposed in a processing chamber 100. While not discussed here in detail, the substrate support 115 is typically disposed in a plasma processing chamber, such as an etching chamber. The processing chamber 100 may be utilized alone or, as a processing module of an integrated semiconductor substrate processing system, or cluster tool. The processing chamber 100 may have a body 128 coupled to a ground 129.

The body 128 of the processing chamber 100 may have sidewalls 103, a lid 184 and a bottom surface 109. The sidewalls 103, lid 184 and bottom surface 109 define an interior volume 116. The interior volume 116 of the processing chamber 100 is a high vacuum vessel that is coupled through a throttle valve (not shown) to a vacuum pump 134. In operation, the substrate is placed on the substrate support 115 and the chamber interior is pumped down to a near vacuum environment.

A showerhead 120 is disposed proximate the lid 184 and within the interior volume 116. One or more gases are introduced from a gas panel 160 via the showerhead 120 into the interior volume 116 of the processing chamber 100. The showerhead 120 may be coupled to an RF power source 132 through a matching network 124. The gas from the showerhead 120 may be ignited into a plasma 118 in the interior volume 116 by applying the power from the RF power source 132 to the showerhead 120. The plasma may be used to etch a feature in a substrate 144 during processing and then pumped out of the processing chamber 100 through the vacuum pump 134.

The substrate support 115 is disposed below the showerhead 120, which is used to supply various gases into the interior volume 116 of the processing chamber 100. The substrate support 115 generally includes an electrostatic chuck (ESC) 102, a ring assembly 170 having a cover ring 104 and an edge ring 105, a cathode 106 to electrically bias the ESC 102, an insulator pipe 108, a pedestal insulator 110, and a pedestal support 112.

The insulator pipe 108 and the pedestal insulator 110 function to electrically isolate the chamber walls and the substrate support 115, respectively, from the electrical bias applied to the ESC 102. The substrate support 115 may be biased by a DC power supply 152. An RF power source 126 may optionally be coupled to the substrate support 115 through a matching network 122.

The cover ring 104 may be a single piece ring that rests on the edge ring 105 and insulator pipe 108. The substrate 144, when placed onto the substrate support 115, will rest on the ESC 102 and be surrounded by the edge ring 105 and cover ring 104. Since the edge ring 105 and cover ring 104 also focuses the plasma, the edge ring 105 and cover ring 104 are usually made of silicon or quartz and consumed during processing. In one embodiment, the cover ring 104 is formed from a quartz material and the edge ring 105 has a body 190. The body 190 is formed from a silicon containing material. In plasma etch chambers, the cover ring 104 and edge ring 105 protects the ESC 102 from erosion by the plasma as well as controlling the distribution of the plasma near the edge of the substrate 144 during processing. To prevent process drift due to erosion of the cover ring 104 and edge ring 105, the edge ring 105 and or processing chamber 100 incorporates structures for monitoring the wear of the edge ring 105.

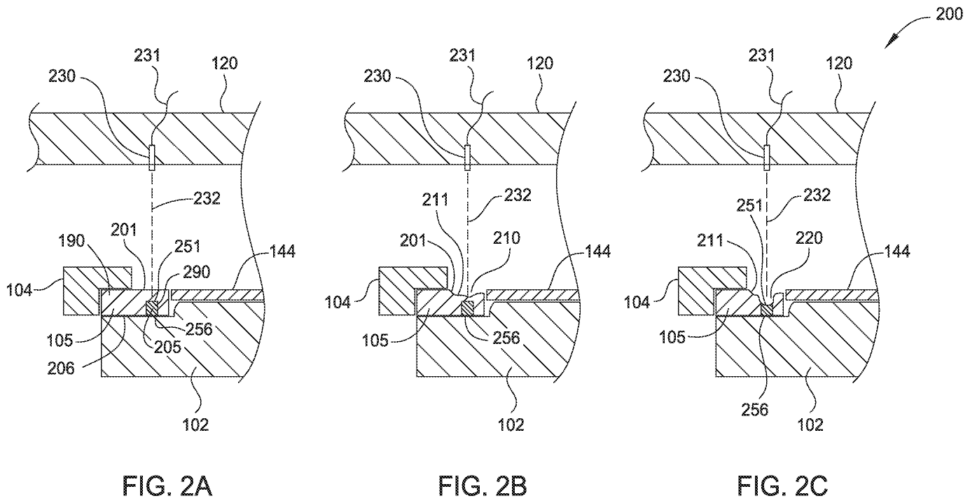

Variations for monitoring the wear on the edge ring 105 are disclosed here as separate embodiments. FIGS. 2A-2C are plan views for a portion of the processing chamber of FIG. 1 in the area of the ring assembly 170 according to a first embodiment of the invention. FIG. 2A shows a portion of the showerhead 120 disposed vertically above the ESC 102. The ESC 102 has the cover ring 104 and a first embodiment of the edge ring 105.

The body 190 of the edge ring 105 has a top surface 201 exposed to the plasma environment of the processing chamber 100. The body 190 of the edge ring 105 has a bottom surface 206. The bottom surface 206 of the edge ring 105 is disposed on the ESC 102. The body 190 additionally has a wear indicator material 290 embedded therein. For example, the wear indicator material 290 may be a pin 205 or slug of material, a layer of material, or other feature different than the material of the body 190 and suitable to detect as the edge ring 105 is worn by plasma. The wear indicator material 290 may be formed from a material different than the body 190 and having detectable different properties. For example, the wear indicator material 290 may have a reflectivity different than the body 190.

In the embodiment of FIGS. 2A through 2C, the wear indicator material 290 will be discussed in reference to the pin 205. However, it should be appreciated by one skilled in the art that the wear indicator material 290 may be another suitable feature, such as the annular ring. The pin 205 has an upper surface 251 disposed nearest, but spaced below, the top surface 201 of the edge ring 105. Likewise, the pin 205 has a lower surface 256 disposed nearest the bottom surface 206 of the edge ring 105. The lower surface 256 of the pin 205 may extend to the bottom surface 206 of the edge ring 105 such that the bottom surface 206 of the edge ring 105 is substantially coplanar with the lower surface 256 of the pin 205. Alternately, the lower surface 256 of the pin 205 may be disposed between the top surface 201 and bottom surface 206 of the edge ring 105. In one embodiment, the pin 205 is fully encapsulated by the edge ring 105. In a second embodiment, the lower surface 256 of the pin 205 is accessible along or through an opening in the bottom surface 206 of the edge ring 105. In other embodiments, the wear indicator material 290 may be an annular layer of material disposed within the body 190 of the edge ring 105.

The pin 205 may be placed in the bottom surface 206 of the edge ring by mechanical or chemical techniques. For example, a hole may be formed in the bottom surface 206 of the edge ring 105 and the pin 205 may be inserted therein. The pin 205 may be adhered therein or pressed fit therein. Optionally, the pin 205 may be covered over with an additional layer of material for the edge ring 105 such as a sheet of silicon or by a deposition of silicon to cover the pin 205 and form the bottom surface 206 of the edge ring 105. Alternately, the pin 205 may be formed in the edge ring 105 using plasma processing techniques or 3D printing. The pin 205 is a layer of material different than the material of the body 190 of the edge ring 105 positioned at a predetermined depth from the top surface 201 of the edge ring 105 that will get exposed and detected as erosion of the top surface 201 occurs. For example, the pin 205, or wear indicator material 290, may be formed from quartz while the edge ring 105 is formed from a silicon containing material such as SiC.

A sensor 230 may be positioned above the edge ring 105. The edge ring may have an alignment feature. The alignment feature may be a key, pin, or other suitable device for orienting the edge ring 105 with the sensor 230. The sensor 230 may be attached to the showerhead 120. In one embodiment, the sensor 230 is disposed in the showerhead 120. The sensor 230 may have a line of sight 232 focused on the pin 205 (or said location) in the edge ring 105. The sensor 230 may be coupled via an optical or electrical transmission line 231 to the controller 180. The sensor 230 may be configured to operate in the absence of plasma, i.e., while processing of the substrate 144 is not occurring. Alternatively, the sensor 230 may be disposed outside of the chamber 100 looking through a window at the edge ring 105.

During processing, the edge ring 105 is eroded by the plasma. FIG. 2B illustrates erosion 211 along the top surface 201 of the edge ring 105. The erosion 211 begins to form a trough 210 in the edge ring 105. The sensor 230 and pin 205 may be positioned such that the line of sight 232 is directed at the trough 210. The sensor 230 may detect optical or acoustic signals as the top surface 201 of the edge ring 105 wears away, thinning the amount of edge ring 105 material over the pin 205, and ultimately, when sufficiently eroded, exposing the pin 205. The sensor 230 may provide feedback to the process equipment for maintaining process uniformity while the edge ring 105 is experiencing erosion.

In FIG. 2C, the erosion 211 of the top surface 201 has progressed to a point where the trough 210 is now an opening 220 exposing the upper surface 251 of the pin 205. As the upper surface 251 of the pin 205 becomes exposed, the metrology changes may be detected by means of optical/acoustic signals gathered by the sensor 230. The pin 205 may have a reflectance different than the reflectance of the top surface 201 to promote efficient detection. In this manner the erosion may be monitored during processing and a signal provided by the pin 205 may be indicative of reaching a threshold for erosion of the edge ring 105. The depth from the top surface 201 to the upper surface 251 of the pin 205 may be based on process drift data associated with allowable erosion of the edge ring 105. Upon detection of the erosion 211 reaching the pin 205, a signal may be generated indicating the erosion exceeds the threshold. For example, the signal may be sent to a controller, or operator, and the processing chamber 100 may be scheduled for preventative maintenance and the ring assembly 170 replaced.

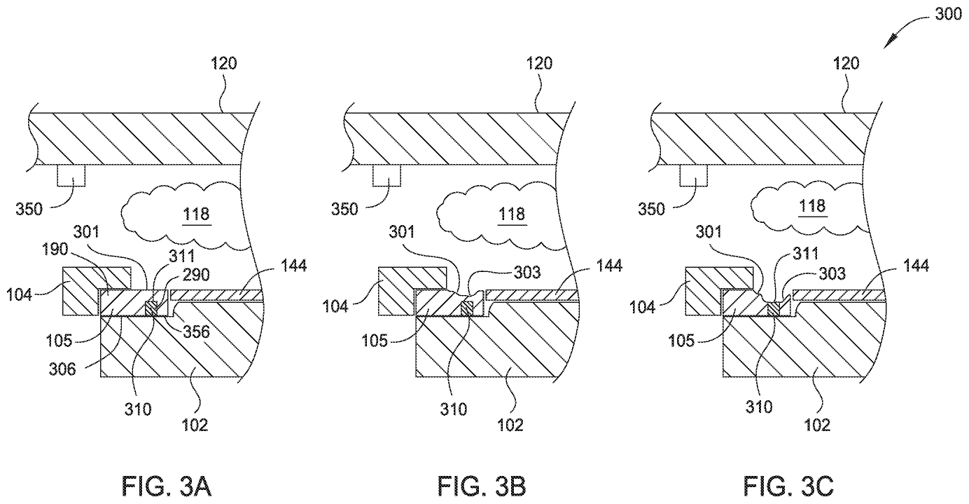

FIGS. 3A-3C are plan views for a portion of the processing chamber of FIG. 1 in the area of the ring assembly 170 according to a second embodiment of the invention. FIG. 3A shows a portion of the showerhead 120 disposed vertically above the ESC 102. The ESC 102 has the cover ring 104 and a second embodiment of the edge ring 105.

The body 190 of the edge ring 105 has a top surface 301 exposed to the plasma 118 in the processing chamber 100. The edge ring 105 has a bottom surface 306. The bottom surface 306 of the edge ring is disposed on the ESC 102. The body 190 of the edge ring 105 additionally has a signal spike material 310 embedded therein. As will be discussed below, the signal spike material 310, when eroded by the plasma, may introduce particles into the interior volume 116 detectable by a sensor 350. The signal spike material 310 may be in the shape of a plug or annular ring having an upper surface 311 disposed nearest the top surface 301 of the edge ring 105. The signal spike material 310 has a lower surface 356 disposed nearest the bottom surface 306 of the edge ring 105. The lower surface 356 of the signal spike material 310 may extend to the bottom surface 306 of the edge ring 105 such that the bottom surface 306 of the edge ring 105 is substantially coplanar with the lower surface 356 of the signal spike material 310. Alternately, the lower surface 356 of the signal spike material 310 may be disposed between the top surface 301 and bottom surface 306 of the edge ring 105. In one embodiment, the signal spike material 310 is fully encapsulated by the edge ring 105. In a second embodiment, the lower surface 356 of the signal spike material 310 is accessible along or through an opening in the bottom surface 306 of the edge ring 105.

The signal spike material 310 may be placed in the bottom surface 306 of the edge ring by mechanical or chemical techniques. For example, a hole may be formed in the bottom surface 306 of the edge ring 105 and the signal spike material 310 may be inserted therein. The signal spike material 310 may be adhered therein or pressed fit therein. Optionally, the signal spike material 310 may be covered over with an additional layer of material for the edge ring 105 such as a sheet of silicon or by a deposition of silicon to cover the signal spike material 310 and form the bottom surface 306 of the edge ring 105. Alternately, the signal spike material 310 may be formed in the edge ring 105 using plasma processing techniques or 3D printing. The signal spike material 310 is a layer of material different than the material of the body 190 of the edge ring 105 positioned at a predetermined depth from the top surface 301 of the edge ring 105 that will get exposed and detected as erosion of the top surface 301 occurs. For example, the signal spike material 310 may be formed from SiO, a florescence material, or other suitable material which emits photons when eroded by the plasma 118.

The sensor 350 may be disposed in the interior volume 116. In one embodiment, the sensor 350 is attached to the showerhead 120. In another embodiment, the sensor is attached to the body 128 of the processing chamber 100. The sensor 350 may detect particles in the chamber environment, i.e., interior volume 116. The sensor 350 may detect emissions from the plasma processing such as erosion of the silicon in the edge ring 105, particles in the plasma 118, as well as the signal spike material 310. The sensor 350 may be coupled via an optical or electrical transmission line to the controller 180. The sensor 230 may be configured to operate in the presence of plasma, i.e., while processing is occurring on the substrate 144. The sensor 230 may be a spectrometer that detects changes in plasma properties, a laser that activates the material that will get exposed after erosion, a capacitance measurement sensor if placed in ESC, an ion-selective electrode, or other suitable device.

During processing, the body 190 of the edge ring 105 is eroded by the plasma. FIG. 3B illustrates erosion 303 along the top surface 301 of the edge ring 105. The erosion 303 begins to forms a depression in the top surface 301 of the body 190. The signal spike material 310 is still covered by material from the body 190 and therefore not in contact with the plasma 118. The sensor 350 monitors for photons from the signal spike material 310.

In FIG. 3C, the erosion 303 of the top surface 301 has progressed to a point where the signal spike material 310 is exposed at the upper surface 311 to the plasma 118. The plasma 118 may cause particles from the signal spike material 310 to enter into the interior volume 116 of the processing chamber. These particles may be photons, ions, or other trace material which are detectable while not harming the processing operations on the substrate 144. The depth from the top surface 301 to the upper surface 311 of the signal spike material 310 may be based on the permissible amount of erosion allowed on the edge ring 105 before process drift data for a given application becomes unacceptable. Upon detection of the signal spike material 310 by the sensor 350, a signal is sent to indicate the presence of particles from the spike material 310 in the interior volume 116. The processing chamber 100 may be scheduled for preventative maintenance and the ring assembly 170 replaced upon receipt of the signal.

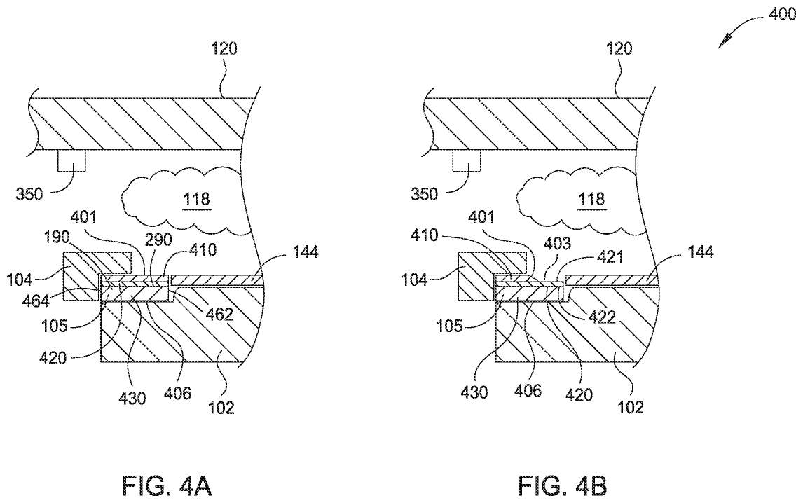

FIGS. 4A-4B are plan views for a portion of the processing chamber of FIG. 1 in the area of the ring assembly 170 according to a third embodiment of the invention. FIG. 4A shows a portion of the showerhead 120 disposed vertically above the ESC 102. The ESC 102 has the cover ring 104 and a third embodiment of the edge ring 105 having a signal spike layer 420.

The body 190 of the edge ring 105 has a top surface 401 exposed to the plasma 118 in the processing chamber 100. The body 190 has a bottom surface 406. The body 190 additionally has an inner edge 462 adjacent to the substrate 144 and an outer edge 464 opposite the inner edge 462. The bottom surface 406 of the body 190 of the edge ring 105 is disposed on the ESC 102. The body 190 has a first layer 410 which encompasses the top surface 401. The first layer 410 is disposed on the signal spike layer 420. The material and function of the signal spike layer 420 is substantially similar to that of the signal spike material 310 discussed in FIGS. 3A-3C. The signal spike layer 420 may encompass the bottom surface 406. Optionally, the body 190 of the edge ring 105 may include a third layer 430. The first layer 410 may be 10 percent of the thickness of the edge ring 105 as measured from the top surface 401 to the bottom surface 406. The signal spike layer 420 may be disposed on the third layer 430. In the embodiment where the body 190 of the edge ring 105 includes the third layer 430, the third layer 430 encompasses the bottom surface 406.

Each of the signal spike layer 420, the first layer 410 and optionally third layer 430 extend from the inner edge 462 to the outer edge 464 of the edge ring 105. The signal spike layer 420 has an upper surface 421 upon which the first layer 410 is disposed upon. The signal spike layer 420 has a lower surface 422 in contract with either the ESC 102 in some embodiments, or the third layer 430 in other embodiments.

The signal spike layer 420 may be formed through mechanical techniques, such sintering or bonding. The signal spike layer 420 may alternately be formed through chemical techniques, such as depositing silicon to cover the signal spike layer 420 with the first layer 410 and optionally the third layer 430 of the body 190 of the edge ring 105. Alternately, the signal spike layer 420 may be formed by 3D printing the edge ring 105 or portions thereof. The signal spike layer 420 is a layer of material different than the material of the body 190 of the edge ring 105 positioned at a predetermined depth from the top surface 401 of the body 190 that will get exposed and detected as erosion of the top surface 401 occurs. For example, the signal spike layer 420 may be formed from SiO, a florescence material, or other suitable material which would emit photons when eroded by the plasma 118.

The sensor 350 may be disposed in the interior volume 116. In one embodiment, the sensor 350 is attached to the showerhead 120. In another embodiment, the sensor is attached to the body 128 of the processing chamber 100. The sensor 350 is substantially described with relation to FIGS. 3A-3C above and detects particles in the chamber environment, i.e., interior volume 116, from the signal spike layer 420 while processing is occurring on the substrate 144.

During processing, the body 190 of the edge ring 105 is eroded by the plasma. FIG. 4B illustrates erosion along the top surface 401 of the edge ring 105. The erosion of the top surface 401 begins to form a depression 403 in the top surface 401 of the body 190. The signal spike layer 420 is eventually uncovered from the edge ring 105 material by erosion of the first layer 410 and the signal spike layer 420 comes into contact with the plasma 118. The sensor 350 monitors for photons from the signal spike layer 420. Upon detection of the signal spike layer 420 by the sensor 350, a signal is sent. The signal may include a message or instructions. For example, the message may indicate the processing chamber 100 should be scheduled for preventative maintenance and the ring assembly 170 replaced.

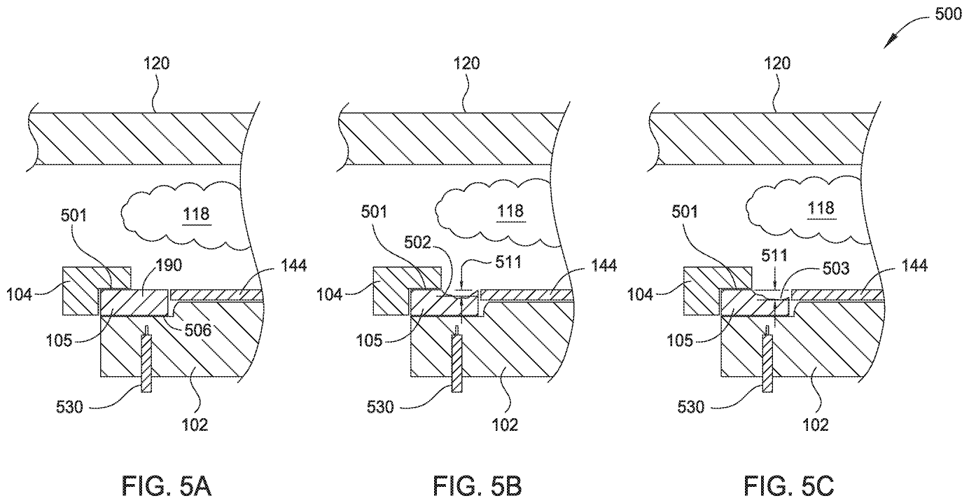

FIGS. 5A-5C are plan views for a portion of the processing chamber of FIG. 1 in the area of the ring assembly according to a fourth embodiment of the invention. FIG. 5A shows a portion of the showerhead 120 disposed vertically above the ESC 102. The ESC 102 has the cover ring 104 and a fourth embodiment for detecting wear on the edge ring 105.

The body 190 of the edge ring 105 has a top surface 501 exposed to plasma 118 in the interior volume 116 of the processing chamber 100. The body 190 has a bottom surface 506. The bottom surface 506 of the edge ring 105 is disposed on the ESC 102. The body 190 is formed from an insulative material such as SiC.

An electrode 530 may be disposed in the ESC 102 and positioned below the edge ring 105. The electrode 530 may be coupled via an optical or electrical transmission line to the controller 180. The electrode 530 may operate analogously as a continuous wave or digitally with discrete stepping waves. The electrode 530 may operate to measure the resistance of the edge ring 105 by coupling with the plasma 118, i.e., while processing of the substrate 144 is occurring, or other time when plasma is present within the interior volume 116.

During processing, the top surface 501 of the body 190 of the edge ring 105 is eroded by the plasma. FIG. 5B illustrates erosion 502 along the top surface 501 of the body 190. The erosion 502 begins to form a depression 511 in the body 190. The electrode 530 may determine the thickness of the edge ring 105 by measuring the resistance across the body 190 of the edge ring 105. The depression 511 reduces the resistance of the edge ring 105 as opposed to the edge ring 105 showing no erosion, such as shown in FIG. 5A. A signal may be sent to indicate the status of process parameters or the edge ring 105. For example, the signal may contain information concerning an estimate for a number of hours left until a preventative maintenance event should be scheduled. Additionally, or alternately, the signal may contain erosion rate information which may be used to adjust process parameters. The signal may be a notice in the form or a message such as a text message, computer message, visual message or other suitable techniques of communicating.

In FIG. 5C, the erosion 502 of the top surface 501 has progressed to a point where the depression 511 has reached a threshold value 503, i.e., a minimum acceptable resistance. At the threshold value 503, the body 190 of the edge ring 105 will have eroded to a point where any further erosion may cause unacceptable process drift. Upon the electrode 530 determining the depression 511 have achieved the threshold value 503, a signal may be sent. The signal may communicate the process should stop and the processing chamber 100 may be scheduled for preventative maintenance and the ring assembly 170 replaced.

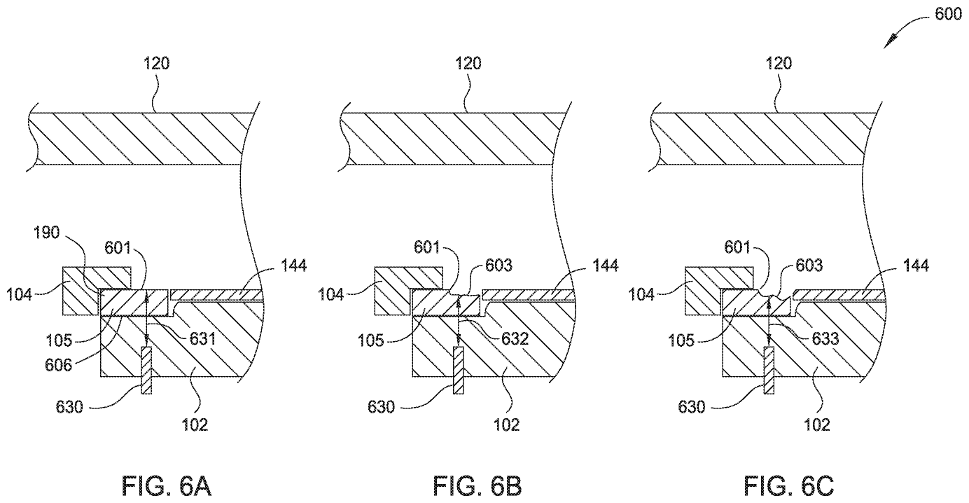

FIGS. 6A-6C are plan views for a portion of the processing chamber of FIG. 1 in the area of the ring assembly according to a fifth embodiment of the invention. FIG. 6A shows a portion of the showerhead 120 disposed vertically above the ESC 102. The ESC 102 has the cover ring 104 and a fifth embodiment for detecting excess wear on the edge ring 105.

The body 190 of the edge ring 105 has a top surface 601 exposed to the interior volume 116 of the processing chamber 100. The body 190 has a bottom surface 606. The bottom surface 606 of the edge ring 105 is disposed on the ESC 102. The body 190 of the edge ring 105 may be formed from SiC, quartz or other suitable materials.

A sensor 630 may be disposed in the ESC 102 and positioned below the edge ring 105. The sensor 630 may be coupled via an optical or electrical transmission line to the controller 180. The sensor 630 may be a microphone for detecting acoustical signals. Alternately, the sensor 630 may be an optical light detector. The sensor 630 may operate to measure the thickness of the edge ring 105. In embodiments where the sensor 630 is a microphone for detecting acoustical signals, accurate measurement of the edge ring can be performed without additional filtering when the plasma, i.e., plasma 118, is not making noise.

During processing, the top surface 601 of the body 190 of the edge ring 105 is eroded by the plasma. FIG. 2B illustrates erosion along the top surface 601 of the body 190. The erosion begins to form a depression 603 in the body 190 of the edge ring 105. The sensor 630 may determine a distance 632 from the sensor 630 to the depression 603 in the top surface 601. The distance 632 may be measured by the sensor 630 using acoustical signal or light detection. The process may be tuned in the chamber 100 in recognition of the erosion of the edge ring 105 measured by the sensor 630.

In FIG. 6C, the depression 603 in the top surface 601 has progressed to a point where the distance 632 has reached a minimum threshold value 633, i.e., maximum acceptable depression 603 in the top surface 601 of the body 190. At achieving the minimum threshold value 633, the body 190 of the edge ring 105 will have eroded to a point where any further erosion may cause unacceptable process drift. Upon the sensor 630 determining the distance 632 have achieved the minimum threshold value 633 a signal may be sent to notify an operator or equipment controller of the condition of the edge ring 105. The processing chamber 100 may be scheduled for preventative maintenance and the ring assembly 170 replaced.

The embodiments disclosed above advantageously provide a methodology for providing process feedback and timing preventative maintenance prior to experiencing unacceptable process drift which may result in substrate defects. The embodiments ensure maximum use of the ring assembly prior to replacement thus reducing expensive and unwarranted replacements. Additionally, certain embodiments, such as the electrode, may be utilized to provide real-time feedback of process and allow tuning of the process.

While the foregoing is directed to embodiments of the present invention, other and further embodiments of the invention may be devised without departing from the basic scope thereof, and the scope thereof is determined by the claims that follow.

What is claimed is:

1. A ring for a plasma processing chamber, the ring comprising:
a body having a top surface, a bottom surface and an inside diameter wall; and
a wear indicator material disposed in the body, the wear indicator material spaced below the top surface of the body, the wear indicator material different than a material comprising the body.

2. The ring of claim 1, wherein the wear indicator material comprises:
a cylindrical pin.

3. The ring of claim 1, wherein the wear indicator material comprises:
an annular band.

4. The ring of claim 1, wherein the wear indicator material comprises:
a reflectivity different than a reflectivity of the body of the edge ring.

5. The ring of claim 1, wherein the wear indicator material comprises:
a material which emits ions that are different than ions emitted from the body when the wear indicator material and the body are exposed to a plasma.

6. The ring of claim 1, wherein the wear indicator material is SiO and the material of the body is quartz.

7. A plasma processing chamber comprising:
a chamber body having in internal volume;
a substrate support disposed in the internal volume;
a ring disposed on the substrate support, the ring comprising:
a body having a top surface, bottom surface and inside diameter wall; and
a wear indicator material disposed in the body, the wear indicator material spaced below the top surface of the body, the wear indicator material different than a material comprising the body; and
one or more sensors positioned to interface with the ring, the one or more sensors configured to detect the wear indicator material.

8. The plasma processing chamber of claim 7, wherein the wear indicator material further comprising:
a SiO material which emits ions different than ions emitted from the body formed from a quartz material when the wear indicating material and body are exposed to a plasma.

9. A method of detecting erosion in a ring assembly, comprising:
obtaining a metric indicative of wear on a ring assembly disposed on a substrate support in a plasma processing chamber prior to processing with plasma in the plasma processing chamber;
monitoring the metric for the ring assembly with a sensor;
determining the metric exceeds a threshold; and
generating a signal in response to the metric exceeding the threshold.

10. The method of claim 9 wherein the ring assembly includes an edge ring and an outer ring, wherein the edge ring has a body having a top surface and contains silicon.

11. The method of claim 10 further comprising:
sensing for erosion of a signal material embedded in the body below the top surface with the sensor disposed in the plasma processing chamber above the edge ring.

12. The method of claim 11 wherein the signal material is a plug accessible through a bottom of the body of the edge ring.

13. The method of claim 11 wherein the signal material is a layer disposed below a silicon containing layer disposed along the top surface of the body.

14. The method of claim 10 further comprising:
measuring a resistance across the edge ring in the presence of the plasma with an electromagnetic sensor disposed below the edge ring; and
modifying the process parameters or maintenance schedule based on the value of the measured resistance.

15. The method of claim 10 further comprising:
measuring a distance across the edge ring in the presence of the plasma with the sensor, wherein the sensor is an electromagnetic sensor embedded in the substrate support.

16. The method of claim 10 further comprising:
measuring a distance to the top surface of the edge ring with the sensor, wherein the sensor is sensor disposed in the plasma processing chamber and exposed to the plasma; and
determining the distance exceeds a maximum threshold.

17. The method of claim 10 further comprising:
measuring a distance to the top surface of the edge ring with the sensor, wherein the sensor is disposed in the substrate support; and
determining the distance exceeds a maximum threshold.

18. The method of claim 17 further comprising:
obtaining from below the edge ring an acoustic signal with an acoustic sensor.

19. The method of claim 17 further comprising:
obtaining from above the edge ring an optical signal with an optical sensor.

20. The method of claim 9 wherein generating a signal comprises:
sending a computer message wherein the computer message may be one or more of an estimate of a number of RF hours left to schedule preventative maintenance, an estimation of the erosion rate for the edge ring, a notice that processing should stop, or a notice the preventative maintenance is required.
